(19) United States
(12) Patent Application Publication
(10) Pub. No.: US 2026/0148878 A1
(43) Pub. Date: May 28, 2026

(54) CABLE AND METHOD OF MANUFACTURING CABLE

(71) Applicant: Sumitomo Electric Industries, Ltd., Osaka (JP)

(72) Inventors: Narumi YOSHIDA, Tochigi (JP); Masamichi YAMAMOTO, Tochigi (JP); Takami SAGISAKA, Tochigi (JP); Shiho HATTORI, Tochigi (JP)

(73) Assignee: Sumitomo Electric Industries, Ltd., Osaka (JP)

(21) Appl. No.: 19/376,299

(22) Filed: Oct. 31, 2025

(30) Foreign Application Priority Data
Nov. 22, 2024 (JP) 2024-203882

(51) Int. Cl. H01B 7/00; H01B 13/06; H05K 9/00

(52) U.S. Cl. CPC H01B 7/0009; H01B 13/06; H05K 9/0098

(57) ABSTRACT

A cable according to an embodiment of the present disclosure is a cable including at least one electrical wire, and a substrate. The electrical wire includes a conductor, a covering that covers the conductor, and an exposed portion at which the conductor is exposed by removal of the covering. An upper surface of the substrate is provided with at least one terminal to be electrically connected to the exposed portion. At least one conductive portion including the exposed portion and the terminal is formed. The conductive portion is covered with an insulating protector. At least a portion of an upper surface of the insulating protector, the portion overlapping the conductive portion when viewed parallel to a thickness direction of the substrate, includes a flat portion.

### CROSS REFERENCE TO RELATED APPLICATIONS

This application claims priority based on Japanese Patent Application No. 2024-203882 filed on November 22, 2024, and the entire contents of the Japanese patent application are incorporated herein by reference.

### TECHNICAL FIELD

The present disclosure relates to a cable and a method of manufacturing a cable.

### BACKGROUND

JP2015-170446A discloses a cable with a connector in which a plane circuit section in which electrical wires and a terminal are electrically connected is covered and protected with a resin. JP2008-112699A discloses an ultrafine coaxial wire harness in which exposed portions of core wires are covered with a cover layer formed of a resin or the like.

### SUMMARY

A cable according to an embodiment of the present disclosure is a cable including at least one electrical wire, and a substrate. The electrical wire includes a conductor, a covering configured to cover the conductor, and an exposed portion at which the conductor is exposed by removal of the covering. An upper surface of the substrate is provided with at least one terminal configured to be electrically connected to the exposed portion. At least one conductive portion including the exposed portion and the terminal is formed. The conductive portion is covered with an insulating protector. At least a portion of an upper surface of the insulating protector, the portion overlapping the conductive portion when viewed parallel to a thickness direction of the substrate, includes a flat portion.

### BRIEF DESCRIPTION OF THE DRAWINGS

FIG. 1 is a schematic view of a cable according to an embodiment of the present disclosure.

FIG. 2 is a cross-sectional view of a cable.

FIG. 3 is a plan view of a connecting portion between electrical wires and a substrate.

FIG. 4 is a cross-sectional view taken along line IV-IV of FIG. 3.

FIG. 5 is a cross-sectional view taken along line V-V of FIG. 3.

FIG. 6 is a process flow diagram of a method of manufacturing a cable according to an embodiment of the present disclosure.

FIG. 7 is a diagram for explaining a process of a method of manufacturing a cable according to an embodiment of the present disclosure.

FIG. 8 is a diagram for explaining a process of a method of manufacturing a cable according to another embodiment of the present disclosure.

FIG. 9 is a cross-sectional view of a connecting portion between electrical wires and a substrate in the case of a multi-stage connection.

### DETAILED DESCRIPTION

Particularly, in medical applications and the like, there is a demand for miniaturization and thinning of cables. In order to achieve thinning, it is important to control the thickness of an insulating protector covering a connecting portion between an electrical wire and a connecting member, but this point has not been sufficiently studied conventionally.

An object of the present disclosure is to provide a thin cable.

### Description of Embodiments of Present Disclosure

First, embodiments of the present disclosure will be listed and described.

(1) A cable according to an embodiment of the present disclosure is a cable including at least one electrical wire, and a substrate. The electrical wire includes a conductor, a covering configured to cover the conductor, and an exposed portion at which the conductor is exposed by removal of the covering. An upper surface of the substrate is provided with at least one terminal configured to be electrically connected to the exposed portion. At least one conductive portion including the exposed portion and the terminal is formed. The conductive portion is covered with an insulating protector. At least a portion of an upper surface of the insulating protector, the portion overlapping the conductive portion when viewed parallel to a thickness direction of the substrate, includes a flat portion.

When a protective agent is simply dropped and cured, the dropped protective agent forms a dome shape, and thus the upper surface of the insulating protector protecting the conductive portion is not flat, and the thickness of the insulating protector tends to be large. According to the cable, since the upper surface of the protective agent is flat, the insulating protector can be made thin while sufficiently ensuring insulation, and the cable can be made thin.

(2) The cable of the above (1) may further include a plurality of the electrical wires. An upper surface of the substrate may be provided with a plurality of the terminals each corresponding to a respective one of the plurality of electrical wires. A plurality of the conductive portions each including a corresponding one of the exposed portions and a corresponding one of the terminals may be formed, and the plurality of conductive portions may be collectively covered with the insulating protector.

According to the present disclosure, even in the case of a cable including the plurality of electrical wires, a thin cable can be obtained without increasing the number of steps by collectively covering the plurality of conductive portions with a thin insulating protector.

(3) In the above (1) or (2), the insulating protector may include at least one molded side surface. The molded side surface may not intersect with the electrical wire. An electronic component or an unused terminal may be disposed in a direction other than the direction in which the electrical wire extends from the conductive portion, and there is a concern that a problem may occur if the electronic component or the unused terminal is unintentionally covered with the insulating protector. Such a situation can be avoided by providing the side surface that is molded by controlling the spread of the protective agent with a jig.

(4) In the above (3), the molded side surface may be provided so as to be continuous with a side surface of the substrate. According to this configuration, the jig is easily placed during manufacturing, and the productivity is excellent.

(5) In the above (3) or (4), the insulating protector may include a first side surface, a second side surface, and a third side surface. The first side surface, the second side surface, and the third side surface may be each a molded side surface and may be each a flat surface. The first side surface may be arranged to face the terminals. The second side surface and third side surface may be both connected perpendicularly to the first side surface and may be arranged such that the second side surface and third side surface face each other. According to this configuration, it is possible to prevent the protective agent from unintentionally spreading in a direction other than the direction in which the electrical wire extends.

(6) In any one of the above (1) to (5), the flat portion may include a highest portion of the insulating protector, with an upper surface of the terminal as a height reference. The cable can be further thinned by the highest portion of the insulating protector being flat.

(7) In any one of the above (2) to (6), a pair of the flat portions may share a common surface, the pair of flat portions overlapping at least a pair of adjacent conductive portions among the plurality of conductive portions when viewed parallel to the thickness direction of the substrate. According to this configuration, the flat portion of the upper surface of the insulating protector extends over a wide range, and thus the cable can be further easily made thinner.

(8) In any one of the above (1) to (7), a height of the flat portion may be 100 µm or less, with an upper surface of the terminal as a height reference. According to this configuration, since the insulating protector is thin, the cable can be made thinner.

(9) In any one of the above (1) to (8), the insulating protector may be a cured product of an ultraviolet-curable resin. By using the ultraviolet-curable resin, there is no risk of damaging surrounding members, and the ultraviolet-curable resin is easily molded into a desired shape.

(10) A method of manufacturing a cable according to an embodiment of the present disclosure is a method of manufacturing a cable including an electrical wire and a substrate, the electrical wire including a conductor and a covering configured to cover the conductor, and an upper surface of the substrate being provided with a terminal corresponding to the electrical wire. The method includes: forming a conductive portion including the conductor that is exposed and the terminal to which the conductor is connected by electrically connecting the conductor and the terminal corresponding to the electrical wire to each other, the conductor being exposed by removal of the covering from a portion of the electrical wire; placing a jig on the upper surface of the substrate or at an edge of the substrate; supplying a curable resin to the conductive portion; compressing the curable resin by pressing a pressing member against the jig from above the substrate; and forming an insulating protector configured to cover the conductive portion by curing the curable resin in a state in which the curable resin is compressed by the pressing member. When the protective agent is simply dropped and cured, the dropped protective agent forms a dome shape, and thus the upper surface of the insulating protector protecting the conductive portion is not flat, and the thickness of the insulating protector tends to be large. According to the above method, the insulating protector can be formed flat and thin by curing the protective agent while compressing the protective agent, and the cable can be made thin.

(11) In the above (10), the curable resin may be an ultraviolet-curable resin, and the pressing member may be configured to transmit ultraviolet light. By using the ultraviolet-curable resin, there is no risk of damaging surrounding members, and the ultraviolet-curable resin is easily molded into a desired shape. In addition, according to the configuration, the resin can be cured by irradiating the resin with ultraviolet light through the pressing member, and thus workability is excellent.

(12) In the above (10) or (11), the curable resin may have a viscosity of 100 mPa·s to 100,000 mPa·s. When the viscosity is in the above range, it is easy to sufficiently protect the conductive portion while avoiding the resin from spreading to a portion other than a desired portion.

### Details of Embodiments of Present Disclosure

Specific examples of a cable and a method of manufacturing a cable of the present disclosure will be described below with reference to the drawings. The present invention is not limited to these examples, but is defined by the scope of the claims, and is intended to include all modifications within the meaning and scope equivalent to the scope of the claims. In the drawings, U, D, F, B, R, and L indicate directions in a cable 1, and U indicates upward, D indicates downward, F indicates forward, B indicates backward, R indicates rightward, and L indicates leftward.

### Cable

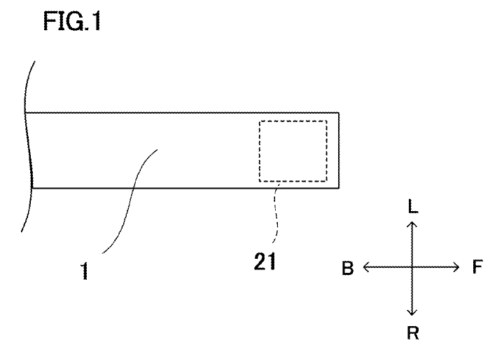

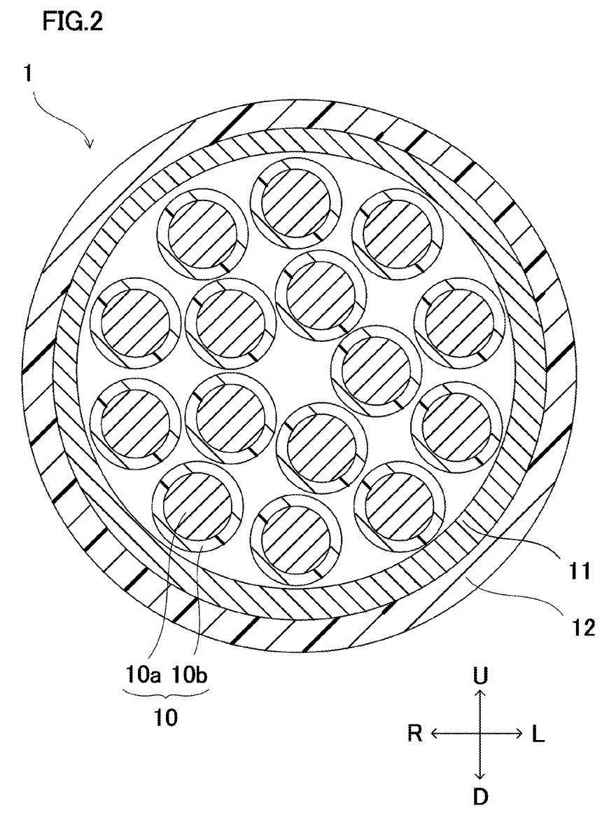

FIG. 1 is a schematic view of the cable 1 according to an embodiment of the present disclosure, and is a view of the cable 1 from upward. FIG. 2 is a cross-sectional view of the cable 1. As shown in FIGS. 1 and 2, the cable 1 includes a plurality of electrical wires 10 and a substrate 21. Only one end of the cable 1 is shown in FIG. 1. A connector may be provided at an end of the cable 1. The configurations of both ends of the cable 1 may be the same or different.

As shown in FIG. 2, the cable 1 may include a shield layer 11 covering the plurality of electrical wires 10 and a cable jacket 12 covering the shield layer 11. Although not shown in FIG. 1, a tape wrapping may be disposed inside the shield layer 11 to cover the plurality of electrical wires 10. An inclusion that fills an internal space of the cable 1 may be used.

Each of the electrical wires 10 includes a conductor 10a and a covering 10b. The conductor 10a is not particularly limited, and a copper wire, a plated copper wire, or a copper alloy wire can be used as the conductor 10a, for example. A single conductor wire or a twisted wire obtained by twisting a plurality of conductor wires may be used. The covering 10b is not particularly limited, and an insulating material such as a polyolefin resin, polyurethane, polyimide, perfluoroalkoxy alkane (PFA), or perfluoroethylene propene copolymer (FEP) can be used.

An outer diameter of the electrical wire 10 may be, for example, 10 μm to 1 mm, 20 μm to 200 μm, 30 μm to 100 μm, or 30 μm to 70 μm. An outer diameter of the conductor 10a may be, for example, 10 μm to 1 mm. A thickness of the covering 10b may be, for example, 1 μm to 500 μm. The outer diameter of the electrical wire 10, the outer diameter of the conductor 10a, and the thickness of the covering 10b are appropriately selected depending on, for example, the use of the cable 1. The electrical wires 10 having different outer diameters may be used in combination. The outer diameter of the cable 1 may be appropriately set depending on the outer diameter and the number of the electrical wires 10, and may be, for example, 50 μm to 50 mm.

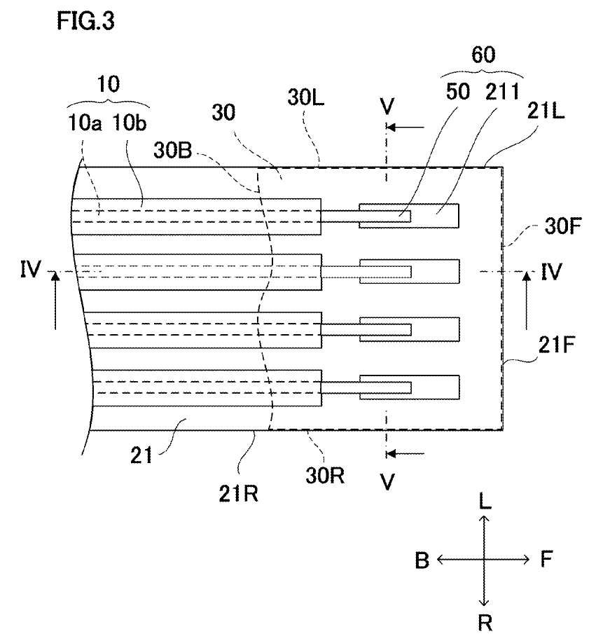

FIG. 3 is a plan view of a connecting portion between the electrical wires 10 and the substrate 21. Although four electrical wires 10 are shown in FIG. 3, the number of electrical wires 10 is not particularly limited. As shown in FIG. 3, the covering 10b is removed at the front end of the electrical wire 10, and the conductor 10a is exposed. In this specification, the conductor 10a exposed at the end of the electrical wire 10 is also referred to as an exposed portion 50. A plurality of terminals 211 are arranged side by side on an upper surface 21U of the substrate 21. The plurality of terminals 211 each corresponds to a respective one of the plurality of electrical wires 10. The exposed portion 50 of the electrical wire 10 and the terminal 211 are electrically connected to each other by, for example, solder (not shown). In this specification, a conductive portion including the exposed portion 50 of the electrical wire 10 and the terminal 211 connected to the exposed portion 50 are collectively referred to as a conductive portion 60. As shown in FIG. 3, the cable 1 of the embodiment includes a plurality of conductive portions 60. The plurality of conductive portions 60 are collectively covered with an insulating protector 30 drawn by a dashed line in FIG. 3, and the connecting portion is protected from moisture and external force.

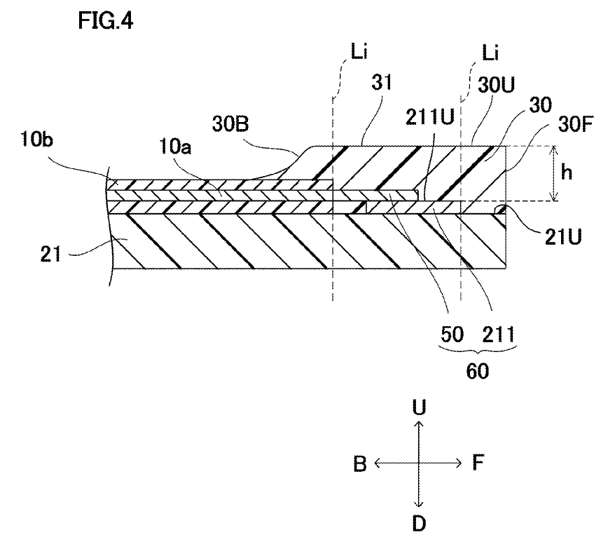

FIG. 4 is a cross-sectional view taken along line IV-IV of FIG. 3. The conductive portion 60 is covered and protected by the insulating protector 30 on the upper surface 21U of the substrate 21. As shown in FIG. 4, in the embodiment, an upper surface 30U of the insulating protector 30 collectively covering the plurality of conductive portions 60 is flat. More specifically, when viewed parallel to a thickness direction of the substrate 21, a portion of the upper surface 30U of the insulating protector 30 (that is, the upper surface 30U in a region sandwiched between two dashed lines Li in FIG. 4), the portion overlapping the conductive portion 60, includes a flat portion 31. The flat portion 31 is a portion having an average height h with an upper surface 211U of the terminal 211 as a height reference. As will be described below, the flat portion 31 is a portion of the insulating protector 30 formed flat using a pressing member 42. The flat portion 31 includes a portion that falls within an error in formation, that is, within a range of ±10% of the average height h. The flat portion 31 may be a portion of which height is 80% or more, 90% or more, or 95% or more of the height of the highest portion of the insulating protector 30. The flat portion 31 may include the highest portion of the insulating protector 30 with the upper surface 211U of the terminal 211 as the height reference.

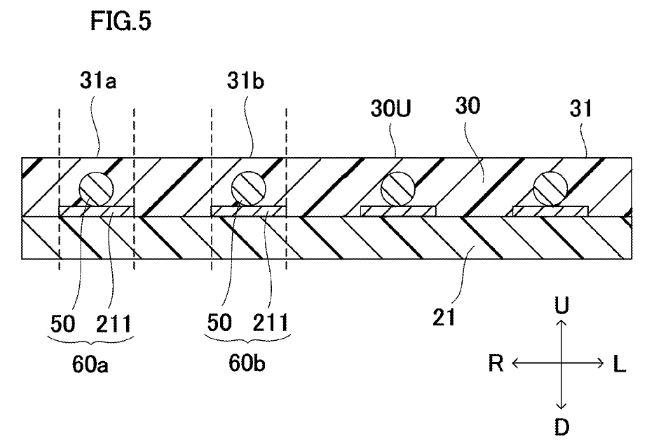

The flat portion 31 occupies 10% or more of an area of the upper surface 30U overlapping the conductive portion 60. The proportion of the flat portion 31 in the upper surface 30U overlapping the conductive portion 60 may be 30% or more, 50% or more, 80% or more, or 100%. As shown in FIGS. 4 and 5, the entire upper surface 30U overlapping the conductive portion 60 may be the flat portion 31.

The insulating protector 30 can be formed by curing a curable resin, for example. Examples of the curable resin used include a thermosetting resin, a moisture-curable resin, and an ultraviolet-curable resin. The use of an ultraviolet-curable resin is preferable because there is no risk of damaging surrounding members by heat or the like and the resin is easily molded into a desired shape. Specific examples of the curable resin include an acrylic resin, an epoxy resin, a urethane resin, and a silicone resin.

A viscosity of the curable resin used for forming the insulating protector 30 may be 100 mPa·s to 100,000 mPa·s, or may be 500 mPa·s to 10,000 mPa·s. When the viscosity is in the above range, it is easy to sufficiently protect the conductive portion while avoiding the resin from spreading to a portion other than a desired portion. The viscosity of the curable resin is a measured value obtained, for example, at 25° C using a cone-plate type viscosimeter (E-type viscosimeter) with the rotation speed set at 10 rpm.

In a conventional cable, an insulating protector is formed by simply dropping a protective agent such as a resin onto a conductive portion at a connecting portion between a conductor and a substrate and curing the protective agent. Since the dropped protective agent forms a dome shape, an upper surface of the insulating protector that protects the conductive portion is not flat, and the thickness of the insulating protector tends to be large. In particular, in recent years, there has been an increasing demand for miniaturization and thinning of cables, and as the area onto which the protective agent is dropped becomes smaller, it tends to become more difficult to control the thickness of the insulating protector. It is conceivable to reduce the thickness of the insulating protector by using a resin having a low viscosity, but in this case, there is a problem that the resin spreads over a wide range even to an unintended portion.

According to a cable 1 of the embodiment, a portion of the upper surface 30U of the insulating protector 30, the portion overlapping the conductive portion 60, includes the flat portion 31. Thus, by controlling the height of the insulating protector 30 to a height necessary and sufficient for protecting the conductive portion 60, the cable can be made thinner than the conventional cable. An example of a method of forming the insulating protector 30 having the upper surface 30U including the flat portion 31 is described below.

In the embodiment, the insulating protector 30 may have at least one molded side surface. In FIG. 3, side surfaces 30F, 30L and 30R of the insulating protector 30 are the molded side surfaces. The molded side surface is a side surface formed by curing a resin after fixing the shape of the resin along a jig. The jig may be any jig. A rear edge portion 30B of the insulating protector 30 in FIG. 3 has an indefinite shape and is not a molded side surface. The molded side surface may be a flat surface, a curved surface, or may include a plurality of surfaces. An example of a method of forming a molded side surface is described below. As shown in FIG. 3, the molded side surfaces 30F, 30L, 30R of the insulating protector 30 do not intersect with the plurality of electrical wires 10. The rear edge portion 30B, which is not molded, intersects with the plurality of electrical wires 10. By providing the insulating protector 30 with the molded side surface at a position not intersecting with the electrical wire 10, it is possible to prevent the resin from spreading to another member of the cable 1 or outside of the substrate 21. The rear edge portion 30B is positioned in a direction (backward B) in which the electrical wire 10 extends when viewed from the conductive portion 60, and the adverse effect is small even if the resin spreads to the backward B, and thus the rear edge portion 30B does not necessarily be a molded side surface. Although the insulating protector 30 is molded by the side surfaces 30F, 30L, and 30R in the above example, the insulating protector 30 does not necessarily be molded by the side surface when there is a side surface that is less adversely affected even if the resin spreads due to the size of the substrate 21, for example. The insulating protector 30 may have at least one molded side surface.

In the embodiment, as shown in FIG. 3, the molded side surfaces 30L, 30F, and 30R of the insulating protector 30 may be provided so as to be continuous with side surfaces 21L, 21F, and 21R of the substrate 21. That is, the boundaries between the molded side surfaces 30L, 30F, and 30R and the respective side surfaces of the substrate 21 may be on the same plane. According to this configuration, as described in the description of the method of manufacturing a cable described below, the jig is easily placed, and productivity is excellent.

In the embodiment, as shown in FIG. 3, the insulating protector 30 may have a first side surface 30F, a second side surface 30L, and a third side surface 30R, the first side surface 30F, the second side surface 30L, and the third side surface 30R are each a molded side surface, the first side surface 30F is arranged to face the plurality of terminals 211, the second side surface 30L and the third side surface 30R are both connected perpendicularly to the first side surface 30F, and the second side surface 30L and the third side surface 30R are arranged such that the second side surface 30L and the third side surface 30R face each other. According to this configuration, it is possible to prevent the insulating protector from unintentionally spreading in a direction other than the direction (backward B) in which the electrical wire 10 extends.

In the embodiment, the height h of the flat portion 31 of the upper surface 30U of the insulating protector 30 may be 100 μm or less, with the upper surface 211U of the terminal 211 as a height reference. The height h of the flat portion 31 means an average height of the flat portion 31. When the height h of the flat portion 31 is in this range, the cable can be miniaturized. The height h of the flat portion 31 may be 40 μm to 100 μm, or 50 μm to 90 μm, with the upper surface 211U of the terminal 211 as a height reference.

FIG. 5 is a cross-sectional view taken along line V-V of FIG. 3. In FIG. 5, the flat portions 31 overlapping the conductive portions 60 share a common surface (corresponding to 30U in FIG. 5). A pair of flat portions 31 overlapping at least a pair of adjacent conductive portions 60 among the plurality of conductive portions 60 when viewed parallel to a thickness direction of the substrate 21 may share a common surface. In FIG. 5, a conductive portion 60a and a conductive portion 60b are a pair of conductive portions 60 adjacent to each other. A flat portion 31a overlapping the conductive portion 60a and a flat portion 31b overlapping the conductive portion 60b adjacent to the conductive portion 60a are the pair of flat portions 31. The common surface of the pair of flat portions 31 overlapping the conductive portions 60 specifically means a surface formed flat using a common pressing member 42. The common surface includes an error in formation, that is, a range in which the height of any position in each flat portion 31 is within ±10% of the height h of the common surface, with the upper surface 211U of the terminal 211 as a height reference.

### Method of Manufacturing Cable

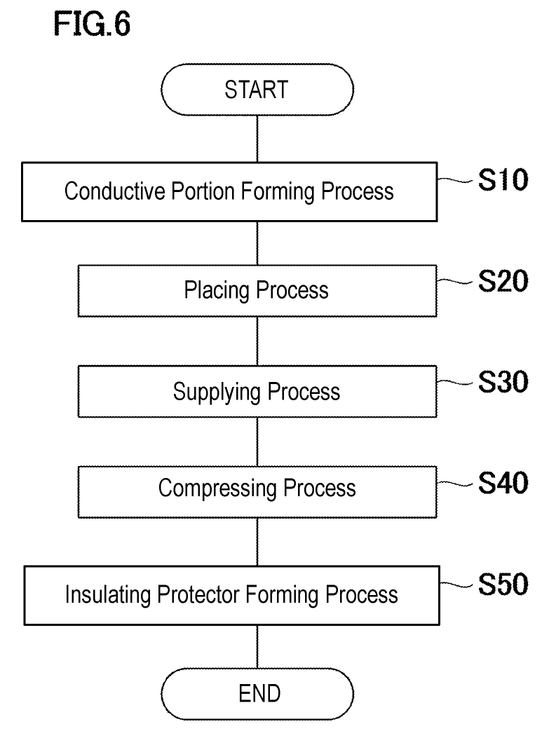

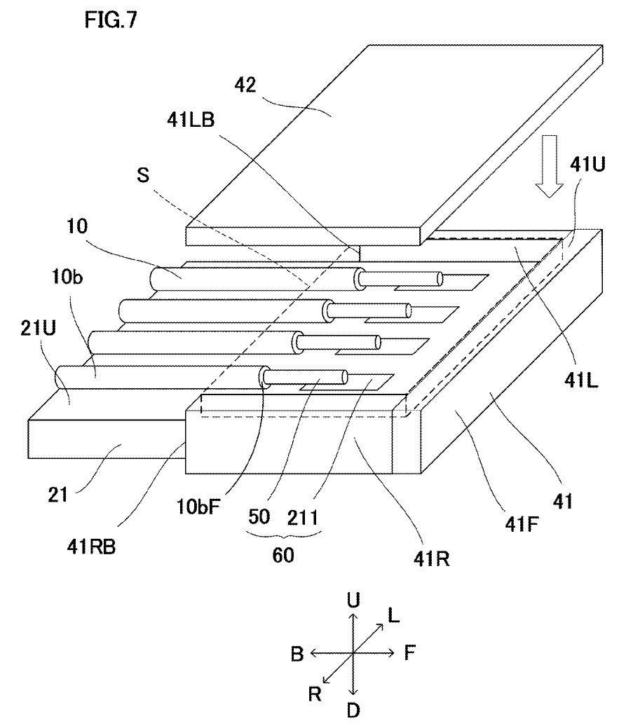

Next, a method of manufacturing a cable of the present disclosure will be described. FIG. 6 is a process flow diagram of a method of manufacturing a cable according to an embodiment of the present disclosure. As shown in FIG. 6, the method of manufacturing of the embodiment includes a conductive portion forming process S10, a placing process S20, a supplying process S30, a compressing process S40, and an insulating protector forming process S50. In the following description, a case of manufacturing the cable 1 is taken as an example, and the reference numerals of the respective constituent elements already described are referred to as appropriate. FIG. 7 is a perspective view for explaining a process of forming the insulating protector 30 on the substrate 21 in the method of manufacturing the cable according to the embodiment.

First, in the conductive portion forming process S10, the conductive portion 60 is formed, the conductive portion 60 including the conductor 10a that is exposed and the terminal 211 to which the conductor 10a is connected by electrically connecting the conductor 10a and the terminal 211 corresponding to the electrical wire 10 to each other, the conductor being exposed by removal of the covering 10b from a portion of the electrical wire 10. The conductor 10a and the terminal 211 are connected by soldering, for example. In the embodiment, since the cable 1 includes the plurality of electrical wires 10, the plurality of conductive portions 60 are formed in the conductive portion forming process S10.

In the placing process S20, a jig 41 is placed on the upper surface 21U of the substrate 21 or at an edge of the substrate 21. FIG. 7 shows a state in which the conductive portion forming process S10 and the placing process S20 are completed. As shown in FIG. 7, in the process of forming the insulating protector 30 in the embodiment, the jig 41 and the pressing member 42 are used. The jig 41 has portions 41F, 41L, and 41R. The portion 41L and the portion 41R face each other, and the portion 41F and the portion 41L and the portion 41R are orthogonal to each other, so that the jig 41 has a U-shape. Although the portions 41F, 41L, and 41R are shown as independent members in FIG. 7, the jig 41 may be formed by combining a plurality of members or may be formed integrally. The jig 41 has a shape along a front edge of the substrate 21, and the jig 41 is placed such that each of the portions 41F, 41L, and 41R abuts on the respective side surfaces of the substrate 21 in the placing process S20. Typically, a rear end portion 41RB of the portion 41R and a rear end portion 41LB of the portion 41L are located backward of a front end 10bF of the covering 10b. An upper surface 41U of the jig 41 is flat and is higher than at least the exposed portion 50 of the conductor 10a. When the jig 41 is placed at the edge of the substrate 21, a space S having a substantially rectangular parallelepiped shape surrounded by the jig 41 on three sides is formed on the upper surface 21U of the substrate 21. The plurality of conductive portions 60 are included in the space S.

The pressing member 42 is, for example, a plate member. The pressing member 42 has a size capable of covering at least the space S surrounded by the jig 41 from above. As the pressing member 42, for example, a resin plate such as an acrylic plate or glass can be used.

After the placing process S20, a curable resin is supplied to the space S including the conductive portions 60 surrounded by the jig 41 in the supplying process S30. The supplied curable resin does not spread over the entire space S at this time, and typically becomes a droplet shape.

Next, as shown in FIG. 7, the compressing process S40 is performed in which the pressing member 42 is pressed against the jig 41 from above the substrate 21. By the compressing process S40, the curable resin is compressed to flatten the upper surface and to fill the entire space S surrounded by the jig 41 with the curable resin. When there is an excessive amount of curable resin, the curable resin flows out to backward where the electrical wire 10 extends. When the pressing member 42 is pressed against the jig 41, the pressing member 42 and the conductive portions 60 overlap each other when viewed parallel to the thickness direction of the substrate 21, and the conductive portions 60 are included in the space S, so that the conductive portions 60 can be reliably covered with the curable resin.

Next, the insulating protector forming process S50 is performed in which the curable resin is cured in a state where the pressing member 42 is pressed against the jig 41 to form the insulating protector 30. For example, when the curable resin is an ultraviolet-curable resin, the curable resin is irradiated with ultraviolet light. The insulating protector 30 obtained by the insulating protector forming process S50 collectively covers the plurality of conductive portions 60. At this time, since the curable resin is compressed from above by the pressing member 42, the flat portion 31 is formed in the upper surface 30U of the insulating protector 30 at least in the region overlapping the conductive portions 60. Further, the front side surface 30F, the left side surface 30L, and right side surface 30R of the insulating protector 30 along the portions 41F, 41L, and 41R of the jig 41 become the molded side surfaces. By the above processes, the insulating protector 30 as shown in FIGS. 3 and 4 can be formed. In addition, the curable resin may not fill a part (for example, a corner or an end) of the space S. The side surfaces 30F, 30L, and 30R being the molded side surfaces means that the side surfaces are molded except for such a part.

Since the insulating protector 30 formed by the above processes includes the flat portion 31 in the upper surface 30U, the cable can be made thinner than the conventional cable. In addition, when the jig 41 is placed at the edge of the substrate 21 as in the embodiment, the jig 41 can be easily placed, and thus productivity is excellent.

In the embodiment, the curable resin may be an ultraviolet-curable resin, and the pressing member 42 may be made of a material that transmits ultraviolet light. When the pressing member 42 is made of a material that transmits ultraviolet light, the resin can be cured by irradiation with ultraviolet light through the pressing member 42, and thus workability is excellent.

In the embodiment, the viscosity of the curable resin may be 100 mPa·s to 100,000 mPa·s, or 500 mPa·s to 10,000 mPa·s. When the viscosity is in the above range, it is easy to sufficiently protect the conductive portion 60 while avoiding the resin from spreading to a portion other than a desired portion.

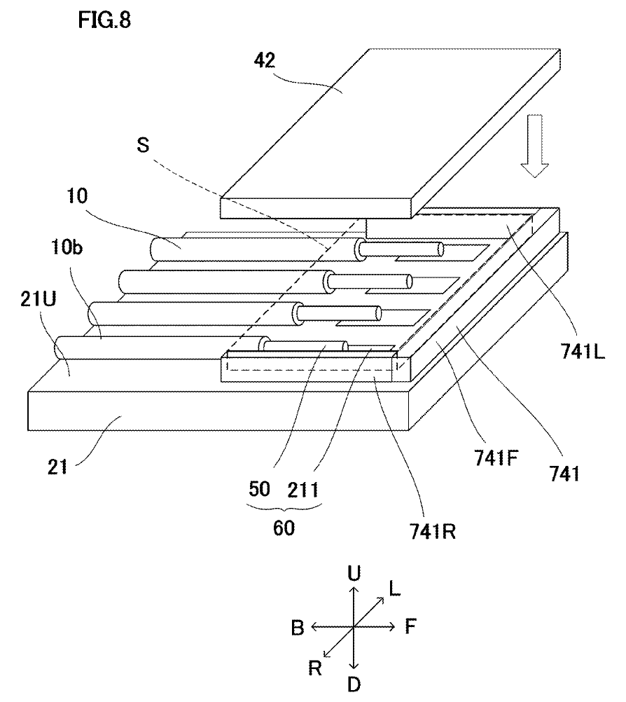

FIG. 8 is a perspective view for explaining a process of forming the insulating protector 30 on the substrate 21 by a method of manufacturing the cable 1 according to another embodiment of the present disclosure. Description of the contents overlapping with the embodiment shown in FIG. 7 described above will be omitted as appropriate, and configurations different from the embodiment shown in FIG. 7 will be described.

In the embodiment shown in FIG. 8, a jig 741 is used instead of the jig 41 shown in FIG. 7. When the insulating protector 30 is formed in the embodiment, the jig 741 is placed on the upper surface 21U, not at the edge of the substrate 21. The jig 741 has portions 741F, 741L, and 741R, and has the same U-shape as the jig 41 of FIG. 7. As shown in FIG. 8, the space S surrounded on three sides by the portions 741F, 741L, and 741R of the jig 741 is generated. In the configuration shown in FIG. 8, the curable resin is supplied to the space S, and the pressing member 42 is pressed against the jig 741 from above to compress and cure the curable resin, whereby the insulating protector that collectively covers the plurality of conductive portions 60 can be obtained. The insulating protector 30 obtained in the embodiment is not formed at the front, left, or right edges of the substrate 21. Thus, for example, when there is an unused terminal 211 (not shown) that is not connected to the exposed portion 50 on the left or right of the terminal 211 connected to the exposed portion 50 on the substrate 21, the conductive portion 60 can be protected while the unused terminal 211 is not covered with the insulating protector. For example, when there is a side surface that is less adversely affected by the spread of the resin due to the position of the unused terminal 211, the side surface does not necessarily be molded. The insulating protector 30 may have at least one molded side surface.

Although the cable and the method of manufacturing the cable of the present disclosure have been described with reference to specific embodiments, the present disclosure is not limited to these embodiments.

In the above description, the example in which the entire upper surface 30U overlapping the conductive portion 60 (that is, the upper surface 30U in the region sandwiched between the two dashed lines Li in FIG. 4) is flat has been shown, but it is sufficient that the flat portion 31 is provided in at least a portion of the upper surface overlapping the conductive portion.

In the above description, an example in which the electrical wire is an insulated electrical wire including a conductor and a covering has been described, but the electrical wire is not limited to the insulated electrical wire, and may be, for example, a coaxial electrical wire. In addition, although an example in which a plurality of electrical wires are covered with a shield layer and a cable jacket has been described, the shield layer and the cable jacket are not essential in the present disclosure. That is, the cable of the present disclosure may be a cable in which the electrical wire is exposed without including the shield layer and the cable jacket. The number of electrical wires 10 is not limited to four, and may be two or more.

In the above description, an example in which the shape of the substrate in a plan view is a rectangle is shown, but the shape of the substrate is not particularly limited, and may be a polygonal shape or a shape in which at least a part of the side surface is a curved surface. The shape of the jig can be designed as appropriate in accordance with the shape of the substrate, for example.

Although the example of using the U-shaped jig has been described above, the shape of the jig is not particularly limited. For example, when it is sufficient to only prevent the resin from spreading forward with respect to the conductive portion, a rod-shaped jig may be placed at the front edge of the substrate to form an insulating protector. In this case, only the side surface in front of the insulating protector is the molded side surface.

The present disclosure is not limited to a multi-core cable including a plurality of electrical wires, and can also be applied to a single-wire cable. In the case of the single-wire, the cable can be made thinner by providing the flat portion 31 in the upper surface of the insulating protector as in the above-described embodiment.

The present disclosure is not limited to the case where the electrical wire and the terminal are connected on one surface of the substrate, and can be applied to a cable having a double-sided connection. That is, the cable of the present disclosure may be a cable in which terminals are provided on both surfaces of the substrate and electrical wires are connected to respective terminals on both surfaces. In this case, the insulating protectors 30 formed on both surfaces each have the flat portion 31. In the case of the double-sided connection, the "upper surface" of the substrate in the above description means the surface on which the terminal is disposed on the substrate, and does not depend on the orientation of the substrate, as will be appropriately understood by those skilled in the art.

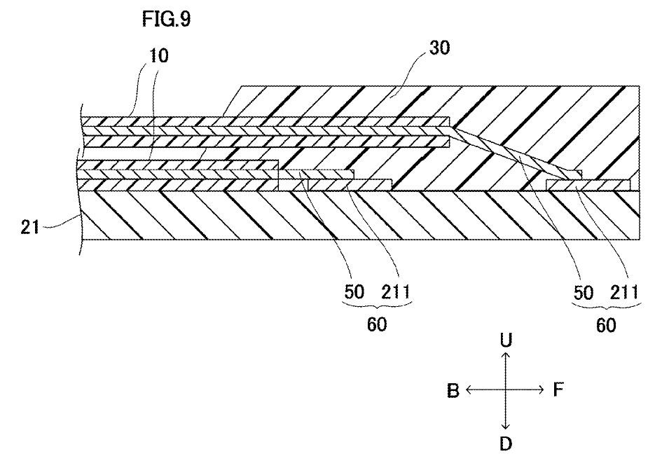

The present disclosure is also applicable to a cable with a multi-stage connection. FIG. 9 is a cross-sectional view of a cable with a two-stage connection according to an embodiment of the present disclosure. As shown in FIG. 9, the multi-stage connection means a configuration in which the plurality of electrical wires 10 are wired so as to overlap in a thickness direction of the substrate 21. In the case of the multi-stage connection, the insulating protector 30 may be formed to collectively cover the electrical wires 10 in a plurality of stages as shown in FIG. 9. The separate insulating protector 30 may be formed for each stage. In this case, after the insulating protector 30 covering the conductive portion 60 of the electrical wire 10 (corresponding to the backward B) of the first stage is formed, the insulating protector 30 covering the conductive portion 60 of the electrical wire 10 (corresponding to the forward F) of the second stage may be formed. The height of the flat portion 31 of the insulating protector 30 in the second stage is higher than the height of the flat portion 31 of the insulating protector 30 in the first stage. In addition, the flat portion 31 of the insulating protector 30 in the first stage is flat, so that the electrical wire 10 in the second stage is easily installed and easily connected to the terminal 211. In addition, the cable can be made thinner. As is clear from the comparison between FIG. 4 and FIG. 9, in the case of the multi-stage connection, the height of the flat portion 31 of the upper surface of the insulating protector with the upper surface of the terminal as the height reference increases as the number of stages of the electrical wire 10 increases. Thus, for example, the height h of the flat portion 31 may be equal to or less than the number of stages of electrical wires ×100 µm, with the upper surface 211U of the terminal 211 as a height reference.

What is claimed is:

1. A cable comprising:
at least one electrical wire; and
a substrate,
wherein the electrical wire includes a conductor, a covering configured to cover the conductor, and an exposed portion at which the conductor is exposed by removal of the covering,
wherein an upper surface of the substrate is provided with at least one terminal configured to be electrically connected to the exposed portion,
wherein at least one conductive portion including the exposed portion and the terminal is formed,
wherein the conductive portion is covered with an insulating protector, and
wherein at least a portion of an upper surface of the insulating protector, the portion overlapping the conductive portion when viewed parallel to a thickness direction of the substrate, includes a flat portion.

2. The cable according to claim 1, comprising:
a plurality of the electrical wires,
wherein an upper surface of the substrate is provided with a plurality of the terminals each corresponding to a respective one of the plurality of electrical wires, and
wherein a plurality of the conductive portions each including a corresponding one of the exposed portions and a corresponding one of the terminals are formed, and the plurality of conductive portions are collectively covered with the insulating protector.

3. The cable according to claim 1,
wherein the insulating protector includes at least one molded side surface, and
wherein the molded side surface does not intersect with the electrical wire.

4. The cable according to claim 3,
wherein the molded side surface is provided so as to be continuous with a side surface of the substrate.

5. The cable according to claim 2,
wherein the insulating protector includes a first side surface, a second side surface, and a third side surface,
wherein the first side surface, the second side surface, and the third side surface are each a molded side surface and are each a flat surface,
wherein the first side surface is arranged to face the terminals, and
wherein the second side surface and third side surface are both connected perpendicularly to the first side surface and are arranged such that the second side surface and third side surface face each other.

6. The cable according to claim 1,
wherein the flat portion includes a highest portion of the insulating protector, with an upper surface of the terminal as a height reference.

7. The cable according to claim 2,
wherein a pair of the flat portions share a common surface, the pair of flat portions overlapping at least a pair of adjacent conductive portions among the plurality of conductive portions when viewed parallel to the thickness direction of the substrate.

8. The cable according to claim 1,
wherein a height of the flat portion is 100 µm or less, with an upper surface of the terminal as a height reference.

9. The cable according to claim 1,
wherein the insulating protector is a cured product of an ultraviolet-curable resin.

10. A method of manufacturing a cable including an electrical wire and a substrate,
the electrical wire including a conductor and a covering configured to cover the conductor,
an upper surface of the substrate being provided with a terminal corresponding to the electrical wire,
the method comprising:
forming a conductive portion including the conductor that is exposed and the terminal to which the conductor is connected by electrically connecting the conductor and the terminal corresponding to the electrical wire to each other, the conductor being exposed by removal of the covering from a portion of the electrical wire;
placing a jig on the upper surface of the substrate or at an edge of the substrate;
supplying a curable resin to the conductive portion;
compressing the curable resin by pressing a pressing member against the jig from above the substrate; and
forming an insulating protector configured to cover the conductive portion by curing the curable resin in a state in which the curable resin is compressed by the pressing member.

11. The method of manufacturing the cable according to claim 10,
wherein the curable resin is an ultraviolet-curable resin, and the pressing member is configured to transmit ultraviolet light.

12. The method of manufacturing the cable according to claim 10,
wherein the curable resin has a viscosity of 100 mPa·s to 100,000 mPa·s.
